(19) United States
(12) Patent Application Publication
(10) Pub. No.: US 2010/0188544 A1
(43) Pub. Date: Jul. 29, 2010

(54) SOLID-STATE IMAGING DEVICE, IMAGING APPARATUS, AND SIGNAL READING METHOD OF SOLID-STATE IMAGING DEVICE

(75) Inventor: Makoto SHIZUKUISHI, Kanagawa (JP)

Correspondence Address: Studebaker & Brackett PC, One Fountain Square, 11911 Freedom Drive, Suite 750, Reston, VA, 20190, US

(73) Assignee: FUJIFILM CORPORATION, Tokyo (JP)

(21) Appl. No.: 12/692,264

(22) Filed: Jan. 22, 2010

(30) Foreign Application Priority Data
Jan. 26, 2009 (JP) 2009-014231

(51) Int. Cl. H04N 5/335

(52) U.S. Cl. 348/308; 348/E05.091

(57) ABSTRACT

A solid-state imaging device includes a plurality of pixel portions, each of the pixel portions includes: a semiconductor photoelectric conversion portion for generating holes according to an amount of incident light and storing the generated holes; a semiconductor floating diffusion layer for converting the holes generated in the photoelectric conversion portion into a voltage corresponding to an amount of the generated holes; and a transistor having a gate electrode which is connected to an output of the floating diffusion layer and an electron storage portion which is disposed under the gate electrode and an amount of electrons stored in which varies depending on a voltage applied to the gate electrode, and the solid-state imaging device further includes: a reading circuit as defined herein.

### CROSS-REFERENCE TO RELATED APPLICATIONS

This application claims the benefit of Japanese Patent Application JP 2009-014231, filed Jan. 26, 2009, the entire content of which is hereby incorporated by reference, the same as if set forth at length.

### FIELD OF THE INVENTION

The present invention relates to a solid-state imaging device, an imaging apparatus, and a signal reading method of a solid-state imaging device.

### BACKGROUND OF THE INVENTION

US-A-2007-0221823 proposes a CMOS solid-state imaging device in which a global shutter is realized in such a manner that charges generated in all photodiodes (PDs) are transferred to respective floating diffusion layers (FDs) and voltage signals corresponding to potential variations of the FDs are read out while the timing is shifted on a line-by-line basis.

However, in this solid-state imaging device, since voltage signals are read out while the timing is shifted on a line-by-line basis, the standby time to reading-out of voltage signals varies depending on the line. As a result, noise or the like that enters each FD from its neighborhood varies from one line to another to cause image quality degradation.

The amount Q of charge that can be stored in each FD is determined by the product of its capacitance C and the power source voltage V that is supplied to it. In CMOS solid-state imaging devices, usually, since power is supplied to all circuits from a single power source, the above-mentioned power source voltage V is constant. Therefore, to increase the sensitivity, it is necessary to reduce the capacitance C. However, if the capacitance C is reduced, the FD is saturated sooner and hence a wide dynamic range cannot be attained. Conversely, if priority is given to increase of the dynamic range, the capacitance needs to be increased and hence high sensitivity cannot be attained. That is, in the solid-state imaging device disclosed in US-A-2007-0221823, it is difficult to attain both of high sensitivity and a wide dynamic range.

Furthermore, in the solid-state imaging device disclosed in US-A-2007-0221823 which operates on a single power source, if the source follower output becomes higher than the power source voltage, dielectric breakdown, a punchthrough phenomenon, or the like occurs to disable correct operation of the circuits.

### SUMMARY OF THE INVENTION

The present invention has been made under the above circumstances, and an object of the invention is therefore to provide a solid-state imaging device capable of attaining both of high sensitivity and a wide dynamic range and increasing the reliability and the image quality, a signal reading method of the solid-state imaging device, and an imaging apparatus having the solid-state imaging device.

The invention provides a solid-state imaging device comprising plural pixel portions, each of the pixel portions comprising a semiconductor photoelectric conversion portion for generating holes according to an amount of incident light and storing the generated holes; a semiconductor floating diffusion layer for converting the holes generated in the photoelectric conversion portion into a voltage corresponding to an amount of the generated holes; and a transistor having a gate electrode which is connected to an output of the floating diffusion layer and an electron storage portion which is disposed under the gate electrode and an amount of electrons stored in which varies depending on a voltage applied to the gate electrode, the solid-state imaging device further comprising a reading circuit for reading out a variation in a threshold voltage of the transistor that is caused by a variation in an amount of electrons stored in the electron storage portion as an imaging signal corresponding to the amount of the holes generated in the photoelectric conversion portion.

The invention also provides an imaging apparatus comprising the above solid-state imaging device.

The invention further provides a signal reading method of a solid-state imaging device, comprising a converting step of converting holes generated in a semiconductor photoelectric conversion portion of each pixel portion of the solid-state imaging device into a voltage corresponding to an amount of the generated holes by means of a semiconductor floating diffusion layer provided in the pixel portion; a control step of controlling, using the voltage generated by the converting step, a gate electrode of a transistor provided in the pixel portion and having the gate electrode and an electron storage portion which is disposed under the gate electrode and an amount of electrons stored in which varies depending on a voltage applied to the gate electrode; and a reading-out step of reading out a variation in a threshold voltage of the transistor that is caused by the control step as an imaging signal corresponding to the amount of the holes generated in the photoelectric conversion portion.

The invention can provide a solid-state imaging device capable of attaining both of high sensitivity and a wide dynamic range and increasing the reliability and the image quality, a signal reading method of the solid-state imaging device, and an imaging apparatus having the solid-state imaging device.

### BRIEF DESCRIPTION OF THE DRAWINGS

FIG. 1A is a schematic plan view showing a general configuration of a solid-state imaging device according to an embodiment of the present invention, and FIG. 1B is a block diagram of each reading circuit.

FIG. 2 is a schematic sectional view showing a general configuration of each of pixel portions shown in FIG. 1A.

FIG. 3 is an equivalent circuit diagram of the pixel portion of FIG. 2.

FIG. 4 shows example potential setting states of individual portions of each pixel portion of the solid-state imaging device of FIG. 1 during a still image shooting operation.

### DETAILED DESCRIPTION OF THE INVENTION

A solid-state imaging device according to an embodiment of the present invention will be hereinafter described with reference to the drawings. This solid-state imaging device is for use in an imaging apparatus such as a digital camera, a digital video camera, or an electronic endoscope.

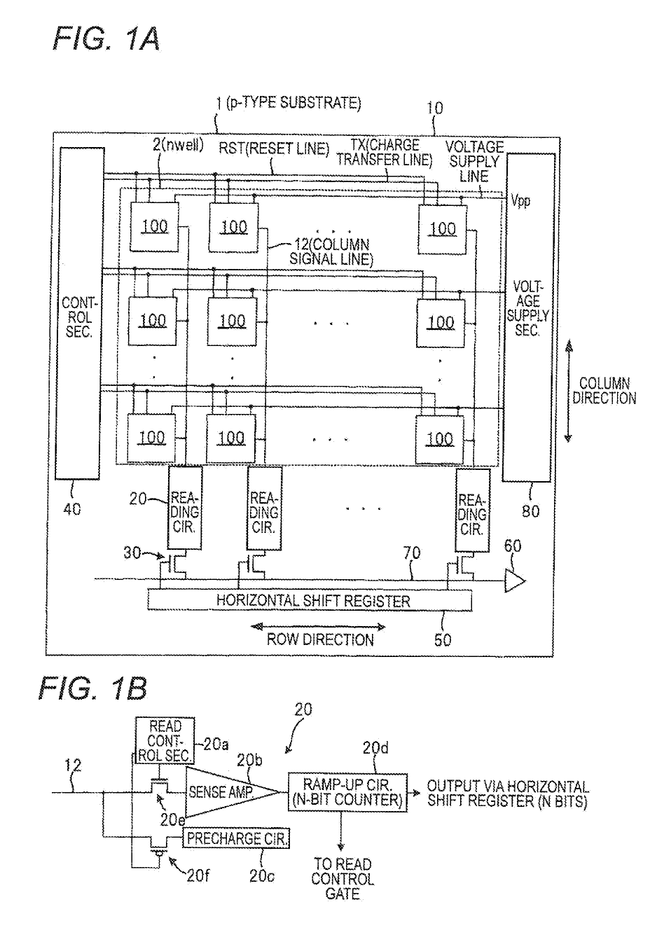

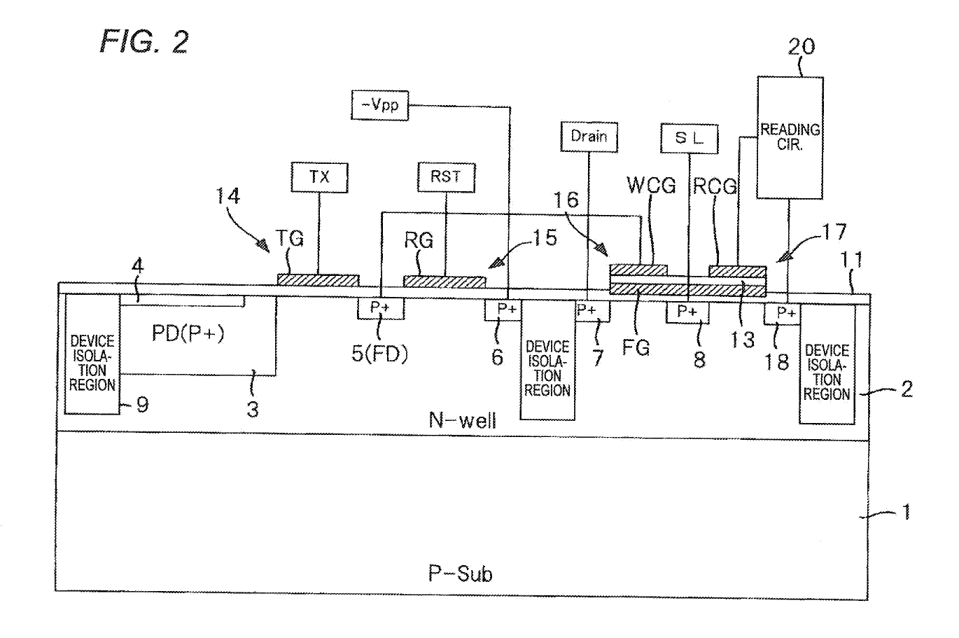

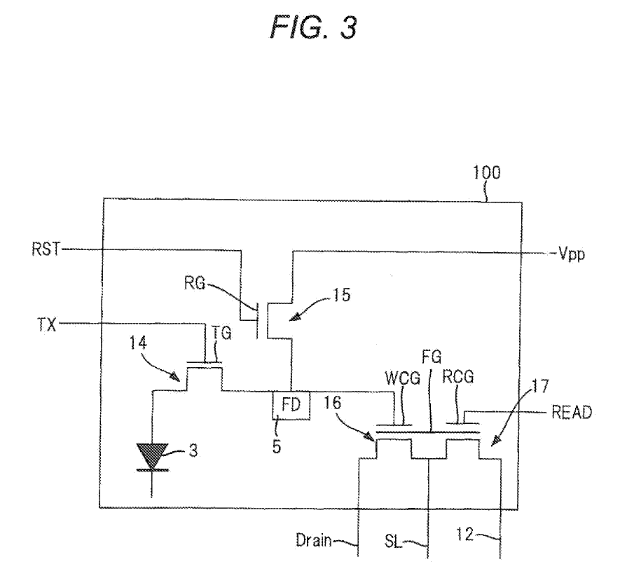

FIG. 1A is a schematic plan view showing a general configuration of the solid-state imaging device according to the embodiment of the invention, and FIG. 1B is a block diagram of each reading circuit. FIG. 2 is a schematic sectional view showing a general configuration of each of pixel portions shown in FIG. 1A. FIG. 3 is an equivalent circuit diagram of the pixel portion of FIG. 2.

The solid-state imaging device 10 is provided with plural pixel portions 100 which are arranged in the same plane in a row direction and a column direction that is perpendicular to the row direction so as to form an array (in this example, a square lattice).

Each pixel portion 100 is provided with a p-type impurity layer 3 in an n-well layer 2 which is formed in a p-type silicon substrate 1. The n-well layer 2 is supplied with a variable voltage from a potential control section (not shown). As shown in FIG. 1, the n-well layer 2 is a single layer which is common to the plural pixel portions 100. Alternatively, separated n-well layers may be provided for the respective pixel portions 100. A photodiode (PD) which functions as a photoelectric conversion portion for generating holes according to the amount of incident light and storing the generated holes is formed by the pn junction of the p-type impurity layer 3 and the n-well layer 2. In the following description, the p-type impurity layer 3 will be referred to as a photoelectric conversion portion 3. The photoelectric conversion portion 3 is what is called a buried photodiode in which an n-type impurity layer 4 is formed adjacent to the surface for the purpose of complete depletion and suppression of dark current.

A floating diffusion layer (FD) 5 which is a high-concentration p-type impurity layer is formed on the right of the photoelectric conversion portion 3 so as to be a little spaced from it. A transfer gate TG is formed on the semiconductor substrate with a gate insulating layer 11 interposed in between so as to be located between the photoelectric conversion portion 3 and the FD 5. The transfer gate TG is connected to a control section 40 by a charge transfer line TX. The photoelectric conversion portion 3, the FD 5, and the transfer gate TG constitute a charge transfer transistor 14 for transferring holes generated in the photoelectric conversion portion 3 to the FD 5.

A drain region 6 which is a high-concentration p-type impurity region is formed on the right of the FD 5 so as to be a little spaced from it. The drain region 6 is connected to a voltage supply section 80 by a voltage supply line. A reset gate RG is formed on the semiconductor substrate with the gate insulating layer 11 interposed in between so as to be located between the FD 5 and the drain region 6. The reset gate RG is connected to the control section 40 by a reset line RST. The FD 5, the reset gate RG, and the drain region 6 constitute a reset transistor 15 for resetting the potential of the FD 5 to a prescribed reset potential −Vpp.

If holes are transferred from the photoelectric conversion portion 3 to the FD 5 in a state that the potential of the FD 5 has been reset to −Vpp by the reset transistor 15, the potential of the FD 5 is varied according to the amount of transferred holes and the potential variation is output as a voltage. As such, the FD 5 functions as a voltage converting means for converting holes generated in the photoelectric conversion portion 3 into a voltage corresponding to the amount of the holes.

A drain region 7 which is a high-concentration p-type impurity region is formed on the right of the drain region 6 with a device isolation region 9 interposed in between. A source region 8 which is a high-concentration p-type impurity region is formed on the right of the drain region 7 so as to be a little spaced from it. The drain region 7 is connected to the potential control section (not shown) by a drain line Drain and supplied with a variable voltage from the potential control section. The source region 8 is connected to the potential control section (not shown) by a source line SL and supplied with a variable voltage from the potential control section.

A write control gate WCG (gate electrode) is formed over the semiconductor substrate with the gate insulating layer 11 interposed in between so as to be located between the drain region 7 and the source region 8. A floating gate FG which functions as an electron storage portion is formed between the write control gate WCG and the gate insulating layer 11. The floating gate FG and the write control gate WCG are insulated from each other by an insulating layer 13. The drain region 7, the write control gate WCG, the floating gate FG, and the source region 8 constitute a write transistor 16 whose threshold voltage varies according to the voltage as converted by the FD 5.

The write control gate WCG is directly connected to the FD 5. When a voltage is applied to the write control gate WCG from the FD 5, electrons are injected into the floating gate FG from the semiconductor substrate according to the level of the applied voltage and the threshold voltage of the write transistor 16 is varied according to the amount of electrons injected into the floating gate FG. The voltages supplied to the drain region 7, the source region 8, and the n-well layer 2 of the write transistor 16 are made controllable so that hot electrons generated through the band-to-band tunneling as disclosed in JP-A-9-8153 and U.S. Pat. No. 5,687,118 can be injected into the floating gate FG.

A drain region 18 which is a high-concentration p-type impurity region is formed on the right of the source region 8 so as to be a little spaced from it. A read control gate RCG is formed over the semiconductor substrate with the gate insulating layer 11 interposed in between so as to be located between the source region 8 and the drain region 18. The floating gate FG also lies between the read control gate RCG and the gate insulating layer 11, and the floating gate FG and the read control gate RCG are insulated from each other by the insulating layer 13. The source region 8, the read control gate RCG, the floating gate FG, and the drain region 18 constitute a read transistor 17 whose threshold voltage varies according to the voltage as converted by the FD 5.

A ramp-up circuit 20d of a reading circuit 20 is connected to the read control gate RCG, and the reading circuit 20 is connected to the drain region 18 by a column signal line 12.

Although in the embodiment the single floating gate FG is formed so as to be common to the write transistor 16 and the read transistor 17, another structure is possible in which separate floating gates FG are provided for the write transistor 16 and the read transistor 17 and connected to each other by an interconnection.

As described above, each pixel portion 100 includes the photoelectric conversion portion 3, the FD 5, the charge transfer transistor 14, the reset transistor 15, the write transistor 16, and the read transistor 17. The sets of constituent elements of adjoining pixel portions 100 are isolated from each other by a device isolation region 9.

The solid-state imaging device 10 is further equipped with the control section 40 for controlling the charge transfer transistors 14 and the reset transistors 15, the reading circuits 20 for detecting threshold voltages of the read transistors 17, a horizontal shift register 50 for performing a control for sequentially reading, into a signal line 70, as imaging signals, 1-line threshold voltages detected by the respective reading circuits 20, an output amplifier 60 which is connected to the signal line 70, and the voltage supply section 80 for supplying the voltage −Vpp to the FDs 5 of the respective pixel portions 100.

Each reading circuit 20 is provided for the plural pixel portions 100 (arranged in the column direction) of the corresponding column and connected to the drain regions 18 of those pixel portions 100 by the column signal line 12. Each reading circuit 20 is also connected to the read control gates RCG of the pixel portions 100 of the corresponding column.

As shown in FIG. 1B, each reading circuit 20 is equipped with a read control section 20a, a sense amplifier 20b, a precharge circuit 20c, a ramp-up circuit 20d, and transistors 20e and 20f.

In reading an imaging signal from one corresponding pixel portion 100, the read control circuit 20a turns on the transistor 20f so that a drain voltage is supplied from the precharge circuit 20c to the drain region 18 of the pixel portions 100 via the column signal line 12 (precharging). Then, the read control circuit 20a turns on the transistor 20e to render the drain region 18 of the pixel portion 100 electrically continuous with the sense amplifier 20b.

Monitoring the voltage of the drain region 18 of the pixel portion 100, the sense amplifier 20b detects a change in the voltage and informs the ramp-up circuit 20d of the change. For example, the sense amplifier 20b detects a drop of the drain voltage of the precharging by precharge circuit 20c and inverts the sense amplifier output.

Incorporating an N-bit counter (N=10 to 12, for example), the ramp-up circuit 20d supplies a read voltage (e.g., a ramp voltage which increases or decreases gradually) to the read control gate RCG of the pixel portion 100 and outputs a count (a combination of 1s and 0s (N in total number)) corresponding to the value of the read voltage.

If the voltage of the read control gate RCG becomes higher than the threshold voltage of the read transistor 17, the read transistor 17 is rendered conductive and, at that time, the potential of the column signal line 12 that has been precharged drops. The sense amplifier detects this event and outputs an inversion signal. The ramp-up circuit 20d latches a count corresponding to a value of the read voltage at a time point of reception of the inversion signal. In this manner, the variation in the threshold voltage can be read out as an imaging signal.

When one horizontal selection transistor 30 is selected by the horizontal shift register 50, a count that is latched by the ramp-up circuit 20d connected to the selected horizontal selection transistor 30 is output to the signal line 70 and then output from the output amplifier 60 as an imaging signal.

The method for reading out a change in the threshold voltage of the read transistor 17 by each reading circuit 20 is not limited to the above one. For example, a drain current of the read transistor 17 when certain voltages are applied to the read control gate RCG and the drain region 18 may be read out as an imaging signal.

The control section 40 is connected to the transfer gates TG and the reset gates RG of the pixel portions 100 (arranged in the row direction) of each row by the charge transfer line TX and the reset line RST, respectively. The control section 40 thus on/off-controls the charge transfer transistors 14 and the reset transistors 15 by controlling the voltages applied to the transfer gates TG and the reset gates RG.

The voltage supply section 80 is connected to the drain regions 6 of the pixel portions 100 of each row by the voltage supply line, and supplies the voltage −Vpp to the drain regions 6. The solid-state imaging device 10 incorporates an only power source for supplying individual portions of the solid-state imaging device 10 with a power supply voltage Vcc (e.g., 3.3 V) which is lower than the absolute value of the voltage −Vpp, and the voltage supply section 80 generates the voltage −Vpp using the power supply voltage Vcc which is supplied from this power source.

In each pixel portion 100 having the above configuration, when holes are transferred from the photoelectric conversion portion 3 to the FD 5, a voltage as converted by the FD 5 is applied to the write control gate WCG. Electrons are injected into the floating gate FG according to this voltage, whereby the threshold voltage of the write transistor 16 is varied. Since the floating gate FG is common to the write transistor 16 and the read transistor 17, the threshold voltage of the read transistor 17 is also varied according to the above voltage. The change in the threshold voltage of the read transistor 17 is read out by the reading circuit 20 as an imaging signal.

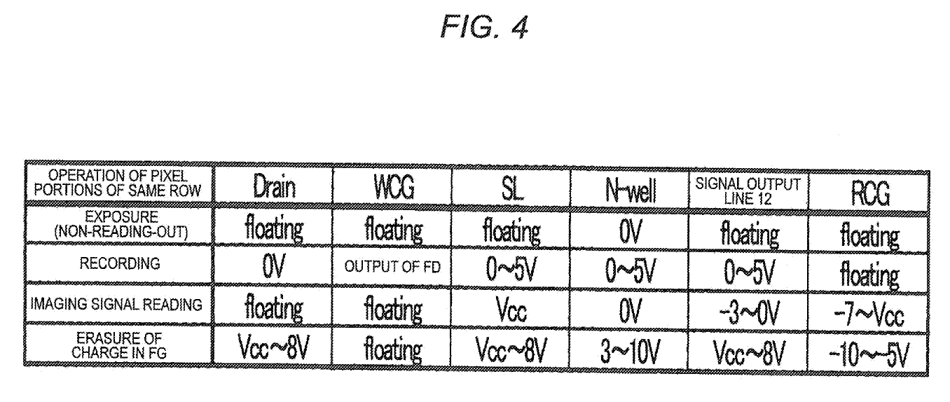

An imaging operation of the solid-state imaging device 10 will be described below. FIG. 4 shows example potential setting states of the drain line Drain, the write control gate WCG, the source line SL, the n-well layer 2, the signal output line 12, and the read control gate RCG of each pixel portion 100 during an imaging operation.

If an instruction to set shooting conditions for shooting of a still image (half depression of the shutter button) is made during shooting of a moving image in a still image shooting mode, AE and AF are performed in the imaging apparatus on the basis of imaging signals that are output from the solid-state imaging device 10 and shooting conditions are set. Then, as soon as the shutter button is depressed fully and a shutter trigger rises, shooting of a still image is started under the thus-set shooting conditions.

More specifically, before a start of a period of an exposure to be performed under the shooting conditions thus set, the control section 40 performs an electronic shutter operation of sweeping out holes generated in each photoelectric conversion portion 3 by applying electronic shutter pulses to the semiconductor substrate. At a start of an exposure period which follows a rise of a shutter trigger, the control section 40 stops the application of electronic shutter pulses to the semiconductor substrate and starts an exposure (i.e., storage of holes in each photoelectric conversion portion 3). During the exposure period, as shown in FIG. 4 (the items on the row of “exposure”), the drain region 7, the write control gate WCG, the source region 8, the drain region 18, and the read control gate RCG are opened and rendered in a floating state and the potential of the n-well layer 2 is set at 0 V.

Immediately before the end of the exposure period, the control section 40 turns on the reset transistor 15 by supplying a pulse to the reset gate RG of every pixel portion 100 and thereby resets the potential of the FD 5 of every pixel portion 100 to −Vpp.

After the resetting has completed and the exposure period has finished, the control section 40 turns on the charge transfer transistor 14 of every pixel portion 100 by supplying a pulse to the transfer gate TG and thereby transfers holes generated in the photoelectric conversion portion 3 to the FD 5. The holes are transferred completely. After the transfer of the holes, the individual portions are set to the states shown in the items of the row “recording” in FIG. 4.

When the holes are transferred to the FD 5 from the photoelectric conversion portion 3, the potential of the FD 5 is increased by ΔV from −Vpp according the amount of transferred charge. The threshold voltage of the write transistor 16 is increased by an amount corresponding to the potential increase ΔV of the FD 5 to Vth2, which is higher than the threshold voltage Vth1 in the state that the potential of the FD 5 was −Vpp.

After the end of the charge transfer, the individual portions are set to the states shown in the items of the row “imaging signal reading” in FIG. 4. More specifically, a drain voltage is applied to the drain region 18 of each pixel portion 100 from the precharge circuit 20c and the drain region 18 is thereby pre charged.

Then, the reading circuits 20 start supply of read voltages to the pixel portions 100 of the first row. When the channel region of the read transistor 17 of each pixel portion 100 of the first row is rendered conductive after the start of supply of the read voltage, the potential of the drain region 18 drops. Each reading circuit 20 latches a count corresponding to a value of the read voltage at a time point of the drop of the potential of the drain region 18. Under the control of the horizontal shift register 50, the latched counts are sequentially output as imaging signals obtained from the pixel portions 100 of the first row.

The same operations as described above (precharging of the drain regions 18, supply of read voltages to the pixel portions 100 of the row concerned, and output of imaging signals) are performed for each of the second and following rows, whereby the still image shooting is completed. After imaging signals have been read from all the rows, as shown in the items on the row of “erasure of charge in FG” in FIG. 4 the control section 40 applies, for example, a voltage of −10 to −5 V to the read control gate RCG of every pixel portion 100 and applies a voltage of 3 to 10 V to the n-well layer 2, whereby the electrons are removed from the floating gate FG into the semiconductor substrate. In this manner, the threshold voltage of the read transistor 17 can be reset and imaging signals can be read out without any problems after the end of the next exposure period.

The potential of the signal output line 12 may be performed by the precharge circuit 20c.

In the solid-state imaging device 10 of FIGS. 1A and 1B, since as described above the output of the FD 5 is connected to the write control gate WCG of the write transistor 16, dielectric breakdown and a punchthrough phenomenon can be prevented even if the absolute value of the reset potential of the FD 5 is higher than that of the power source voltage Vcc. The absolute value of the reset potential of the FD 5 can be set higher than that of the power source voltage Vcc of the solid-state imaging device 10 and the capacitance of the FD 5 can be decreased accordingly. That is, the capacitance of the FD 5 can be decreased while its saturation level is fixed, which in turn makes it possible attain both of a wide dynamic range and high sensitivity. Furthermore, since unnecessary electrons are not prone to enter the floating gate FG from its neighborhood, noise can be suppressed which occurs in a standby period before reading-out of an imaging signal, which contributes to increase in image quality.

In the solid-state imaging device 10 of FIGS. 1A and 1B, an imaging signal is read out as a variation in the threshold voltage of the read transistor 17. Therefore, the maximum value of imaging signals can be increased so as to be approximately equal to or larger than the power source voltage Vcc of the solid-state imaging device 10 and hence the S/N ratio of imaging signals can be increased.

In the solid-state imaging device 10 of FIGS. 1A and 1B, holes generated in the photoelectric conversion portion 3 can be transferred to the FD 5 completely. Therefore, the efficiency of conversion from holes generated in the photoelectric conversion portion 3 to an imaging signal can be increased and hence reduction in sensitivity can be prevented.

In the solid-state imaging device 10 of FIGS. 1A and 1B, a global shutter can be realized merely by providing four transistors in each pixel portion 100. The number of transistors can be made lower than in conventional cases and hence the solid-state imaging device 10 can be miniaturized easily. Since the write transistors 16 and the read transistor 17 interrupt light, it is not necessary to consider presence/absence of incident light at the time of reading and no mechanical shutter is necessary. Furthermore, since the above-described configuration can be realized without the need for altering, to a large extent, the conventional buried photodiode, floating diffusion amplifier, etc. which were developed in CCD image sensors and CMOS image sensors, a high-sensitivity, high-image-quality, low-noise CMOS image sensor having a global shutter function can be realized easily.

Furthermore, in the solid-state imaging device 10 of FIGS. 1A and 1B, the potential of the floating gate FG increases as the potential of the FD 5 increases; that is, the light quantity and the imaging signal have a positive correlation. Imaging signals can thus be read out easily.

Example methods for injecting charge into the floating gate FG are hot electron injection in which charge is injected into the floating gate FG using channel hot electrons (CHEs), hot electrons generated through band-to-band tunneling (band-to-band-tunneling-current-induced hot electrons), or the like and tunneling electron injection in which charge is injected into the floating gate FG utilizing Fowler-Nordheim (F-N) tunneling, direct tunneling, or the like.

The solid-state imaging device 10 employs the hot electron injection using hot electrons generated through band-to-band tunneling (for details, refer to JP-A-9-8153 and U.S. Pat. No. 5,687,118). In the solid-state imaging device 10 in which the output of the FD 5 is connected to the write control gate WCG, the absolute value of the voltage supplied to the FD5 can be set higher than that of the power source voltage of the solid-state imaging device 10. However, taking the breakdown voltage etc. of the FD5, the absolute value of −Vpp can be increased to only about two times the absolute value of the power source voltage. In the case of F-N tunneling, it is necessary to apply, to the write control gate WCG, a voltage that is about three to five times the absolute value of the power source voltage. Therefore, with the configuration of the solid-state imaging device 10, the charge injection speed would be too low. The CHE injection is low in injection efficiency.

In flash memories used in USB memories etc., data need to be held for a long time. It is therefore common to set the thickness of a tunneling oxide layer at about 8 to 9 nm and employ the F-N tunneling injection. On the other hand, in the solid-state imaging device 10 in which data need not be held for a long time, low-voltage driving with a thin tunneling oxide layer (e.g., about nm) is possible. The employment of the band-to-band tunneling has an advantage that the speed of the imaging operation can be increased because the electron injection speed is higher than in the case of the CHE injection. These are the reasons why the solid-state imaging device 10 employs the hot electron injection using hot electrons generated through band-to-band tunneling.

In the solid-state imaging device 10 which employs the hot electron injection using hot electrons generated through band-to-band tunneling, the source region and the drain region of each of the write transistor 16 and the read transistor 17 are p-type regions. Accordingly, the photoelectric conversion portion 3, the FD 5, and the drain region 6 are also p-type regions.

Because of a high transfer speed etc., CCD image sensors and CMOS image sensors commonly employ electrons as carriers. Also in the solid-state imaging device 10, it would be preferable that the photoelectric conversion portion 3, the FD 5, and the drain region 6 be n-type regions. However, to make the photoelectric conversion portion 3, the FD 5, and the drain region 6 n-type regions, it is necessary to form a p-well layer in the p-type silicon substrate 1 separately from the n-well layer 2 and to form the photoelectric conversion portion 3, the FD 5, and the drain region 6 in the p-well layer. In this case, the p-well layer and the n-well layer 2 exist adjacent to each other in each pixel portion 100. To form the p-well layer and the n-well layer 2 adjacent to each other, the solid-state imaging device needs to be designed taking into consideration that each well layer will be elongated in the horizontal direction through diffusion by about 30% to 50% of the well depth, which means a limitation in design. On the other hand, US-A-2007-0108371 states that color contamination can be reduced by forming p-channel MOS transistors in each pixel of a CMOS image sensor.

These are the reasons why in the solid-state imaging device 10 the photoelectric conversion portion 3, the FD 5, and the drain region 6 are formed as p-type regions in the n-well layer 2 where the source region and the drain region of each of the write transistor 16 and the read transistor 17 are formed. This configuration makes it possible to reduce color contamination and increase the electron injection efficiency and speed.

In the example of FIG. 2, the source region and the drain region of each of the write transistor 16 and the read transistor 17, the photoelectric conversion portion 3, the FD 5, the drain region 6 are formed in the n-well layer 2 which is formed in the p-type silicon substrate 1. However, the n-well layer 2 can be omitted by employing an n-type silicon substrate. Using the p-type silicon substrate 1 as shown in FIG. 2 provides an advantage that the manufacturing cost can be made lower than in the case of using an n-type silicon substrate.

As described above, this specification discloses the following items:

A solid-state imaging device comprising plural pixel portions, each of the pixel portions comprising a semiconductor photoelectric conversion portion for generating holes according to an amount of incident light and storing the generated holes; a semiconductor floating diffusion layer for converting the holes generated in the photoelectric conversion portion into a voltage corresponding to an amount of the generated holes; and a transistor having a gate electrode which is connected to an output of the floating diffusion layer and an electron storage portion which is disposed under the gate electrode and an amount of electrons stored in which varies depending on a voltage applied to the gate electrode, the solid-state imaging device further comprising a reading circuit for reading out a variation in a threshold voltage of the transistor that is caused by a variation in an amount of electrons stored in the electron storage portion as an imaging signal corresponding to the amount of the holes generated in the photoelectric conversion portion.

With this configuration, since the floating diffusion layer is connected to the gate electrode of the transistor, dielectric breakdown and a punchthrough phenomenon can be prevented even if the absolute value of a reset potential of the floating diffusion layer is higher than that of a power source voltage. The absolute value of the reset potential of the floating diffusion layer can be set higher than that of the power source voltage and the capacitance of the floating diffusion layer can be decreased accordingly. That is, the capacitance of the floating diffusion layer can be decreased while its saturation level is fixed, which in turn makes it possible attain both of a wide dynamic range and high sensitivity. Furthermore, since unnecessary electrons are not prone to enter the electron storage portion of the transistor from its neighborhood, noise can be suppressed which occurs in a standby period before reading-out of an imaging signal, which contributes to increase in image quality.

A solid-state imaging device in which the photoelectric conversion portion, the floating diffusion layer, a source region and a drain region of the transistor are p-type semiconductor regions formed in an n-type semiconductor.

This configuration makes it possible to reduce color contamination and to inject electrons into the electron storage portion using hot electrons generated through band-to-band tunneling. The electron injection speed and efficiency can thus be increased.

A solid-state imaging device in which the n-type semiconductor is an n-well layer formed over a p-type semiconductor substrate.

This configuration enables use of a p-type semiconductor substrate and thereby makes it possible to lower the manufacturing cost.

A solid-state imaging device in which n-well layer is a single layer which is common to the plural pixel portions.

A solid-state imaging device in which the n-type semiconductor is a single semiconductor substrate which is common to the plural pixel portions.

A solid-state imaging device in which the electrons stored in the electron storage portion are hot electrons generated through band-to-band tunneling.

This configuration makes it possible to increase the electron injection efficiency and speed and to thereby increase the sensitivity and the frame rate.

A solid-state imaging device in which the electron storage portion of the transistor is a floating gate, a second transistor is provided whose threshold voltage varies according to a potential variation of the floating gate; and the reading circuit reads out a variation in the threshold voltage of the transistor as an imaging signal using the second transistor.

An imaging apparatus comprising any of the above solid-state imaging devices.

A signal reading method of a solid-state imaging device, comprising a converting step of converting holes generated in a semiconductor photoelectric conversion portion of each pixel portion of the solid-state imaging device into a voltage corresponding to an amount of the generated holes by means of a semiconductor floating diffusion layer provided in the pixel portion; a control step of controlling, using the voltage generated by the converting step, a gate electrode of a transistor provided in the pixel portion and having the gate electrode and an electron storage portion which is disposed under the gate electrode and an amount of electrons stored in which varies depending on a voltage applied to the gate electrode; and a reading-out step of reading out a variation in a threshold voltage of the transistor that is caused by the control step as an imaging signal corresponding to the amount of the holes generated in the photoelectric conversion portion.

What is claimed is:

1. A solid-state imaging device comprising a plurality of pixel portions, each of the pixel portions comprising:
a semiconductor photoelectric conversion portion for generating holes according to an amount of incident light and storing the generated holes;
a semiconductor floating diffusion layer for converting the holes generated in the photoelectric conversion portion into a voltage corresponding to an amount of the generated holes; and
a transistor comprising a gate electrode which is connected to an output of the floating diffusion layer and an electron storage portion which is disposed under the gate electrode and an amount of electrons stored in which varies depending on a voltage applied to the gate electrode, the solid-state imaging device further comprising:
a reading circuit for reading out a variation in a threshold voltage of the transistor that is caused by a variation in an amount of electrons stored in the electron storage portion as an imaging signal corresponding to the amount of the holes generated in the photoelectric conversion portion.

2. The solid-state imaging device according to claim 1, wherein the photoelectric conversion portion, the floating diffusion layer, and a source region and a drain region of the transistor are p-type semiconductor regions formed in an n-type semiconductor.

3. The solid-state imaging device according to claim 2, wherein the n-type semiconductor is an n-well layer formed over a p-type semiconductor substrate.

4. The solid-state imaging device according to claim 3, wherein the n-well layer is a single layer which is common to the plurality of pixel portions.

5. The solid-state imaging device according to claim 2, wherein the n-type semiconductor is a single semiconductor substrate which is common to the plurality of pixel portions.

6. The solid-state imaging device according to any one of claim 1, wherein the electrons stored in the electron storage portion are hot electrons generated through band-to-band tunneling.

7. The solid-state imaging device according to claim 1, wherein:
the electron storage portion of the transistor is a floating gate;
the solid-state imaging device further comprises a second transistor a threshold voltage of which varies according to a potential variation of the floating gate; and
the reading circuit reads out a variation in the threshold voltage of the transistor as an imaging signal using the second transistor.

8. An imaging apparatus comprising the solid-state imaging device according to claim 1.

9. A signal reading method of a solid-state imaging device, comprising:
a converting step of converting holes generated in a semiconductor photoelectric conversion portion of each pixel portion of the solid-state imaging device into a voltage corresponding to an amount of the generated holes by means of a semiconductor floating diffusion layer provided in the pixel portion;
a control step of controlling, using the voltage generated by the converting step, a gate electrode of a transistor provided in the pixel portion and having the gate electrode and an electron storage portion which is disposed under the gate electrode and an amount of electrons stored in which varies depending on a voltage applied to the gate electrode; and
a reading-out step of reading out a variation in a threshold voltage of the transistor that is caused by the control step as an imaging signal corresponding to the amount of the holes generated in the photoelectric conversion portion.
